(19) United States
(12) Patent Application Publication
(10) Pub. No.: US 2025/0147678 A1
(43) Pub. Date: May 8, 2025

(54) DRAM AND CONTROL METHOD FOR THE SAME

(71) Applicant: Research & Business Foundation SUNGKYUNKWAN UNIVERSITY, Suwon-si (KR)

(72) Inventors: JUNGRAE KIM, Suwon-si (KR); Jae Yoon LEE, Suwon-si (KR)

(73) Assignee: Research & Business Foundation SUNGKYUNKWAN UNIVERSITY, Suwon-si (KR)

(21) Appl. No.: 18/935,375

(22) Filed: Nov. 1, 2024

(30) Foreign Application Priority Data
Nov. 3, 2023 (KR) 10-2023-0150978

(51) Int. Cl. G06F 3/06; G11C 11/408; G11C 11/4091

(52) U.S. Cl. CPC G06F 3/0625; G06F 3/0634; G06F 3/0673; G11C 11/4087; G11C 11/4091

(57) ABSTRACT

There is provided a DRAM including a plurality of mats composed of cell arrays, comprising: a first mat including a first cell array that is aligned by first bitlines and first wordlines; a second mat including a second cell array that is adjacent to the first mat and aligned by second bitlines and second wordlines; and a bitline sense amplifier shared by the first bitlines of the first mat and the second bitlines of the second mat, wherein the bitline sense amplifier connected to the first mat is shared only with the second mat.

### BACKGROUND OF THE INVENTION

### Field of the Invention

The present invention relates to a DRAM, a method for controlling the same, and a device for performing the method.

### Description of the Related Art

As is known, a DRAM may mean a general type of memory used as a main memory in a computer and a digital device. The DRAM may temporarily store data and help a central processing unit (CPU) access the data quickly. Such DRAM may be mainly used to store data and instructions required for processes running in applications and operating systems.

Meanwhile, a density of the DRAM has more than doubled over the past 20 years, but an access latency of the DRAM has decreased slightly during the same period and remained almost the same. Although the access latency of the DRAM is one of key factors of system performance, the DRAM has been designed with a priority on the density over the latency.

Therefore, research is required on a new DRAM structure with improved access latency and refresh overhead in memory capacity of a data center having low utilization.

### RELATED ART DOCUMENT

### Patent Document

(Patent Document 1) Korean Patent No. 1995-0014555, published on Jun. 26, 1992

### SUMMARY OF THE INVENTION

An embodiment of the present invention provides a DRAM including a bitline sense amplifier shared by bitlines of each adjacent mat and a method for controlling the same.

The problems to be solved by the present invention are not limited to those described above, and other problems to be solved that are not mentioned may be clearly understood by those having ordinary knowledge of the present invention from the description below.

In accordance with an aspect of the present disclosure, there is provided a DRAM including a plurality of mats composed of cell arrays, comprising: a first mat including a first cell array that is aligned by first bitlines and first wordlines; a second mat including a second cell array that is adjacent to the first mat and aligned by second bitlines and second wordlines; and a bitline sense amplifier shared by the first bitlines of the first mat and the second bitlines of the second mat, wherein the bitline sense amplifier connected to the first mat is shared only with the second mat.

The bitline sense amplifier may include a first input terminal that is connected to one of the first bitlines and a second input terminal that is connected to one of the second bitlines corresponding to the first bitline connected to the first input terminal.

When the basic mode is selected by the mode register and then an address command is received, the first mat may activate one of first interest arrays corresponding to the received address command to provide a data voltage higher than a reference voltage from a cell of at least one of a cell of the first interest arrays to the bitline sense amplifier, and the second mat may deactivate second interest arrays corresponding to the first interest arrays to provide the reference voltage from a cell of at least one of the second interest arrays to the bitline sense amplifier.

when the low-latency mode is selected by the mode register and then an address command is received, the first mat may activate first interest arrays corresponding to the received address command to provide a data voltage higher than a reference voltage from a cell of at least one of the first interest arrays to the bitline sense amplifier, and the second mat may activate second interest arrays corresponding to the first interest arrays to provide an opposite voltage to the data voltage from a cell of at least one of the second interest arrays to the bitline sense amplifier.

When the low-latency mode is selected by the mode register, the first mat and the second mat may store the data voltage and the opposite voltage in each cell corresponding to each of a first bitline and a second bitline connected to the same bitline sense amplifier.

When the low-power mode is selected by the mode register and then an address command is received, the first mat may activate first interest arrays corresponding to the received address command to provide a data voltage lower than a reference voltage from a cell of at least one of the first interest arrays to the bitline sense amplifier, and the second mat may activate second interest arrays corresponding to the first interest arrays to provide an opposite voltage to the data voltage from a cell of at least one of the second interest arrays to the bitline sense amplifier.

The low-power mode may have a second update cycle longer than a first update cycle of the basic mode and the low-latency mode, the mode register may select the basic mode when the memory usage is greater than or equal to reference usage, and select one of the low-latency mode or the low-power mode when the memory usage is less than the reference usage.

When the low-latency mode is selected and then the application driving method is in a standby mode, the mode register may select the low-power mode.

The second cell array may store opposite data or independent data of the first cell array.

In accordance with other aspect of the present disclosure, there is provided a method for controlling a DRAM including a bitline sense amplifier shared by first bitlines of a first mat and second bitlines of a second mat adjacent to the first mat, the method comprising: identifying memory usage and an application operation method of a server to which the DRAM belongs; selecting one of a basic mode, a low-latency mode, or a low-power mode based on the memory usage and the application operating method; and controlling the first mat and the second mat according to the selected mode, wherein the bitline sense amplifier connected to the first mat is shared only with the second mat.

The bitline sense amplifier may include a first input terminal that is connected to one of the first bitlines and a second input terminal that is connected to one of the second bitlines corresponding to the first bitline connected to the first input terminal.

The controlling the first mat and the second mat according to the selected mode may include: receiving an address command after the basic mode is selected; activating first interest arrays of the first mat corresponding to the received address command to provide a data voltage higher than a reference voltage from a cell of at least one of the first interest arrays to the bitline sense amplifier; and deactivating second interest arrays of the second mat corresponding to the first interest arrays to provide the reference voltage from a cell of at least one of the second interest arrays to the bitline sense amplifier.

The controlling the first mat and the second mat according to the selected mode may include: receiving an address command after the low-latency mode is selected; activating first interest arrays of the first mat corresponding to the received address command to provide a data voltage higher than a reference voltage from a cell of at least one of the first interest arrays to the bitline sense amplifier; and activating second interest arrays of the second mat corresponding to the first interest arrays to provide an opposite voltage to the data voltage from a cell of at least one of the second interest arrays to the bitline sense amplifier.

The controlling the first mat and the second mat according to the selected mode may further include storing the data voltage and the opposite voltage in each cell of the first mat and the second mat corresponding to each of the first bitline and the second bitline connected to the same bitline sense amplifier, when the low delay mode is selected.

The controlling the first mat and the second mat according to the selected mode may include: receiving an address command after the low-power mode is selected; activating first interest arrays of the first mat corresponding to the received address command to provide a data voltage lower than a reference voltage from a cell of at least one of the first interest arrays to the bitline sense amplifier; and activating second interest arrays of the second mat corresponding to the first interest arrays to provide an opposite voltage to the data voltage from a cell of at least one of the second interest arrays to the bitline sense amplifier.

The low-power mode may have a second update cycle longer than a first update cycle of the basic mode and the low-latency mode, and the selecting one of the basic mode, the low-latency mode, or the low-power mode may include: selecting the basic mode when the memory usage is greater than or equal to reference usage; and selecting one of the low-latency mode or the low-power mode when the memory usage is less than the reference usage.

The selecting one of the low-latency mode or the low-power mode may further include selecting the low-power mode when the selection changes from the basic mode to the low-latency mode and then the application driving method is in a standby mode.

In the controlling the first mat and the second mat according to the selected mode, it may be controlled whether to store independent data or opposite data in the first mat and the second mat according to the selected mode.

In accordance with another aspect of the present disclosure, there is provided a method for controlling a DRAM including a bitline sense amplifier shared by first bitlines of a first mat and second bitlines of a second mat adjacent to the first mat, the method comprising: identifying memory usage and an application operation method of a server to which the DRAM belongs; selecting one of a basic mode, a low-latency mode, or a low-power mode based on the memory usage and the application operating method; and controlling the first mat and the second mat according to the selected mode, wherein the low-power mode has a second update cycle longer than a first update cycle of the basic mode and the low-latency mode, and the bitline sense amplifier connected to the first mat is shared only with the second mat.

According to an embodiment, by using the structure including the bitline sense amplifiers shared by the bitlines of each adjacent mat, it is possible to dynamically switch the capacity that is not fully utilized in order to improve the latency and power consumption while minimizing the area overhead. As a result, by improving the DRAM access latency by utilizing the unused capacity, it is possible to increase the application speed.

In addition, by dynamically switching the capacity and reducing the times of number of the refresh operation, it is possible to extend the usage time of the battery-driven device.

### BRIEF DESCRIPTION OF THE DRAWINGS

FIG. 1 is a diagram for describing a configuration of a DRAM according to an embodiment of the present invention.

FIG. 2 is a diagram illustrating a typical DRAM mat structure.

FIG. 3 is a diagram for describing an operation of the DRAM of FIG. 2.

FIG. 4 is a diagram illustrating a mat structure of the DRAM according to an embodiment of the present invention.

FIG. 5 is a diagram for describing the operation of the DRAM in the basic mode according to an embodiment of the present invention.

FIG. 6 is a diagram illustrating a mat structure in a mode other than the basic mode of the DRAM according to an embodiment of the present invention.

FIG. 7 is a diagram for describing the operation of the DRAM in the low-latency mode according to an embodiment of the present invention.

FIG. 8 is a diagram for describing the operation of the DRAM in the low-power mode according to an embodiment of the present invention.

FIG. 9 is a flowchart of a method of controlling a DRAM according to an embodiment of the present invention.

FIG. 10 is a graph comparing the energy consumption of the DRAM according to an embodiment of the present invention.

FIG. 11 is a graph comparing refresh current consumption in a low-power mode of a mirror-structured mat according to an embodiment of the present invention.

### DETAILED DESCRIPTION OF THE INVENTION

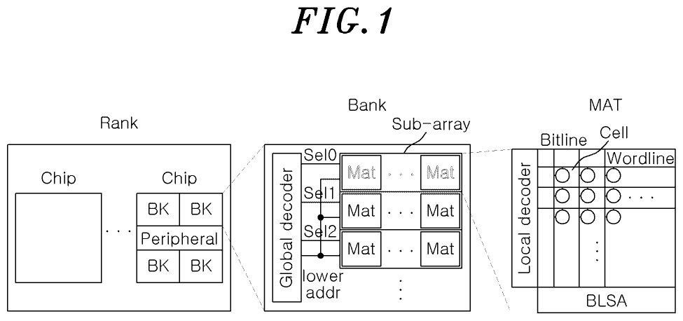

FIG. 1 is a diagram for describing a configuration of a DRAM according to an embodiment of the present invention.

A DRAM 100 of the present invention may refer to a volatile memory called a main memory. The DRAM 100 may be configured as illustrated in FIG. 1. Specifically, the DRAM 100 may have a plurality of ranks representing independent memory portions inside, and a plurality of chips may be included within the ranks. In addition, a plurality of banks are formed in one chip, and these banks may provide an environment in which an address space is divided to simultaneously access multiple data. In addition, one bank is composed of a plurality of mats, and one mat may include a cell array area and a bitline sense amplifier.

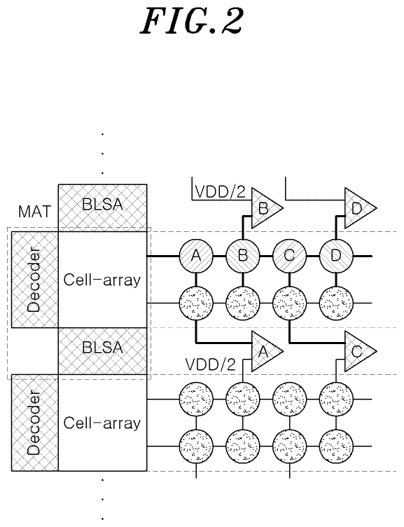

The cell array of the mat is formed by being aligned by bitlines and wordlines, which will be described with reference to FIG. 2.

FIG. 2 is a diagram illustrating a typical DRAM mat structure.

One cell formed by the bitlines and the wordlines may have a value of 1 or 0, and 10⁹ of these 1-bit unit cells gather to form a DRAM having a capacity of 1 Gbit or more.

The DRAM of FIG. 2 may be composed of a plurality of chips to provide a desired data bandwidth. As described in FIG. 1, each chip may include a plurality of banks capable of overlapping multiple requests, and each bank may include a plurality of mats composed of two-dimensional cell arrays.

In this case, data access is performed by activating one of local wordlines of each mat and connecting a cell in a row of the activated wordline to the corresponding local bitline. The bitline sense amplifier may detect a slight change in voltage by charge sharing and amplify the voltage to V_{DD} or GND.

In addition, among address commands received from the outside, a column address may select an output of a sub-array and be transmitted to the outside through local and global input/output ports.

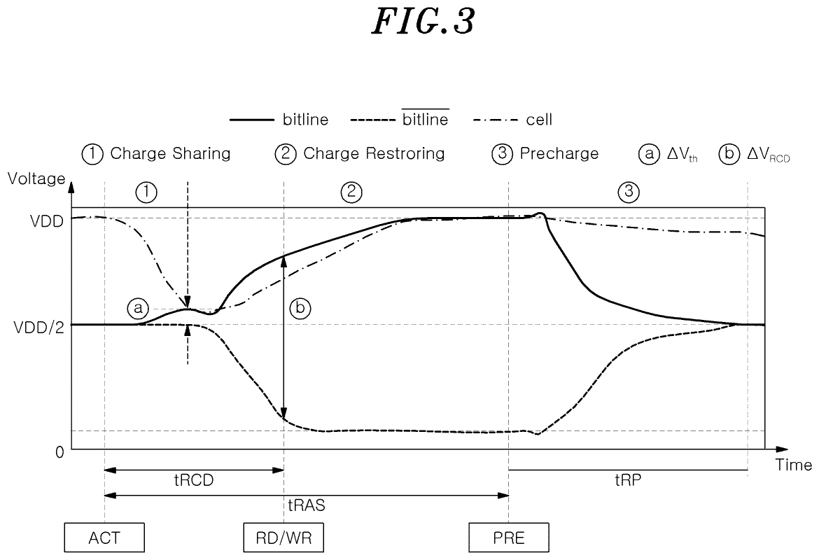

FIG. 3 is a diagram for describing an operation of the DRAM of FIG. 2.

To access the DRAM, three steps such as row activation, data read/write, and precharge are required.

Before the row activation step, in the precharge step, all wordlines may be released and all bitlines may be precharged to V_{DD}/2.

When the row activation command (activation (ACT)) is input, a transistor in a row to be accessed may be turned on. When a cell in an activated row is connected to a local bitline, the charge sharing \textcircled{1} starts, and the slight change in voltage \textcircled{a} may occur in the bitline.

The bitline sense amplifier that detects the slight change in voltage \textcircled{a} may be amplified to a voltage level \textcircled{b} that may read a difference between a bitline and a complementary bitline. Here, the time required to reach the voltage level that may be read in the row activation step to allow the read/write command may be defined as a DRAM timing parameter tRCD.

Thereafter, the bitline sense amplifier may continue to amplify a bitline voltage to the full V_{DD} or GND. In this case, a cell may restore charge \textcircled{2} while still being connected to a bitline. Here, a minimum row activation time required to completely restore the cell may be defined as a DRAM timing parameter tRAS.

After the read/write operation for the cell is completed, a memory controller may execute a precharge command (PRE). When entering the precharge step, the wordline may be deactivated to close the activated row and separate the cell from the bitline.

Then, the bitline may be precharged to V_{DD}/2 for subsequent activation. Here, a minimum time interval \textcircled{3} between the precharge PRE and the activation ACT may be defined as a parameter tRP.

These DRAM cells may leak the stored charges over time. In this case, a maximum period during which a cell may hold enough charge to cause a readable change in voltage may be defined as a refresh cycle.

The DRAM needs to periodically replenish charge through a refresh command (REF) before losing data. In this case, an average interval of the refresh command may be defined as parameter tREFI.

In addition, the refresh command takes a tRFC time, and during this time, it may be impossible to issue a command to the bank.

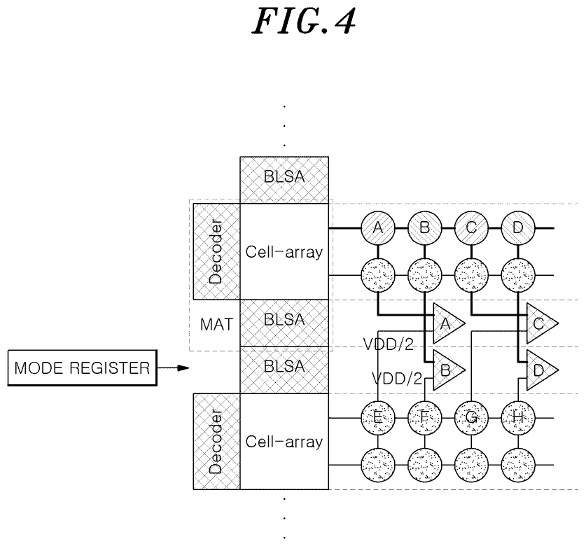

Meanwhile, the DRAMs of FIGS. 2 and 3 have structures for optimizing latency, and may be disadvantageous in terms of area efficiency. To solve this problem, according to an embodiment of the present invention, a DRAM having a structure capable of improving DRAM access latency and power consumption by utilizing a capacity of memory with low utilization may be provided. Hereinafter, the DRAM structure according to an embodiment of the present invention will be described with reference to FIG. 4.

FIG. 4 is a diagram illustrating a mat structure of the DRAM according to an embodiment of the present invention. FIG. 4 illustrates a pair of adjacent mat structures, and it is assumed that an upper mat is a first mat and a lower mat is a second mat.

Referring to FIG. 4, the DRAM according to an embodiment of the present invention may include the first mat, the second mat, and the bitline sense amplifier.

The first mat may include a first cell array aligned by first bitlines and second wordlines, and the second mat may include a second cell array that is adjacent to the first mat and aligned by second bitlines and second wordlines.

The bitline sense amplifier may be shared by the first bitlines of the first mat and the second bitlines of the second mat. Specifically, the bitline sense amplifier may have a first input terminal that is connected to one of the first bitlines and a second input terminal that is connected to one of the second bitlines corresponding to the first bitline connected to the first input terminal. In this way, each of all the first bitlines of the first mat and each of all the second bitlines of the second mat may share the bitline sense amplifier.

Compared to an open bitline structure in which half of the bitlines are connected to an upper bitline sense amplifier and the other half is connected to a lower bitline sense amplifier, the DRAM of FIG. 4 differs in that an upper first mat has a bitline sense amplifier at a lower portion thereof, and a lower second mat has a bitline sense amplifier at an upper portion thereof.

As a result, mat pairs share the bitline sense amplifier, and the first bitline of the first mat and the second bitline of the second mat may move to the bitline sense amplifier without cascading. To implement this, only the position of the bitline sense amplifier needs to change, and there is no need to change the internal structure of the existing open bitline.

Meanwhile, the DRAM according to an embodiment of the present invention may further include a mode register that selects one of a basic mode, a low-latency mode, or a low-power mode based on memory usage of a server to which the DRAM belongs and an application driving method. Based on this mode, the DRAM according to an embodiment of the present invention may control whether to store independent data or opposite data in the first mat and the second mat. As a result, the second cell array may store opposite data or independent data of the first cell array.

Hereinafter, an operation of the DRAM of FIG. 4 for each mode will be described, focusing on an operation of the mode register.

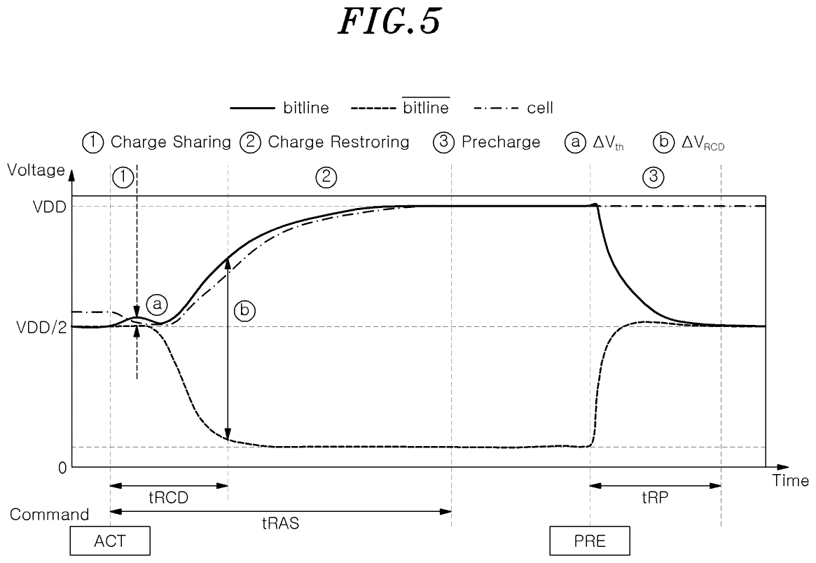

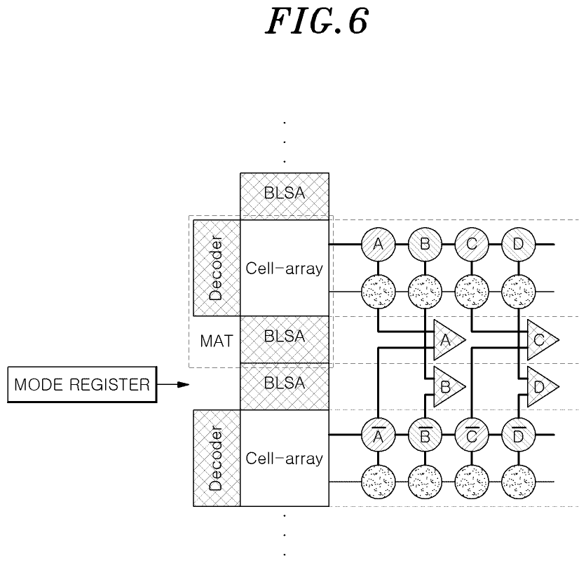

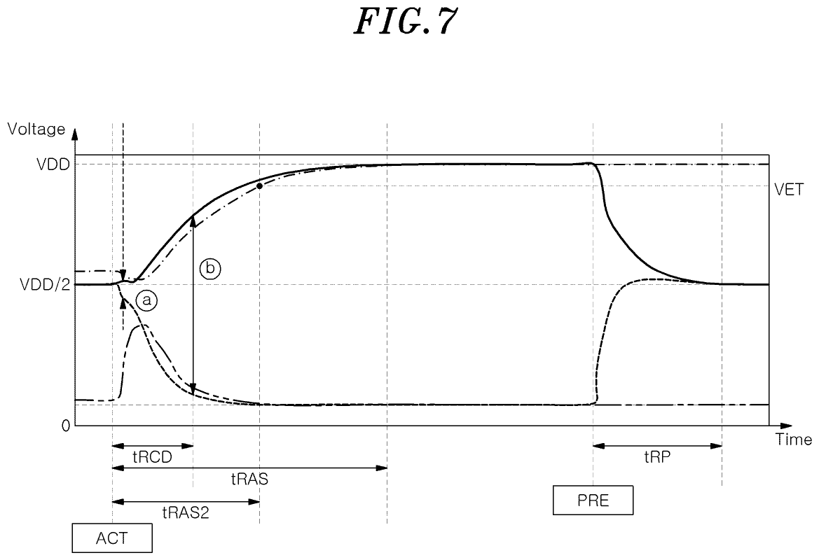

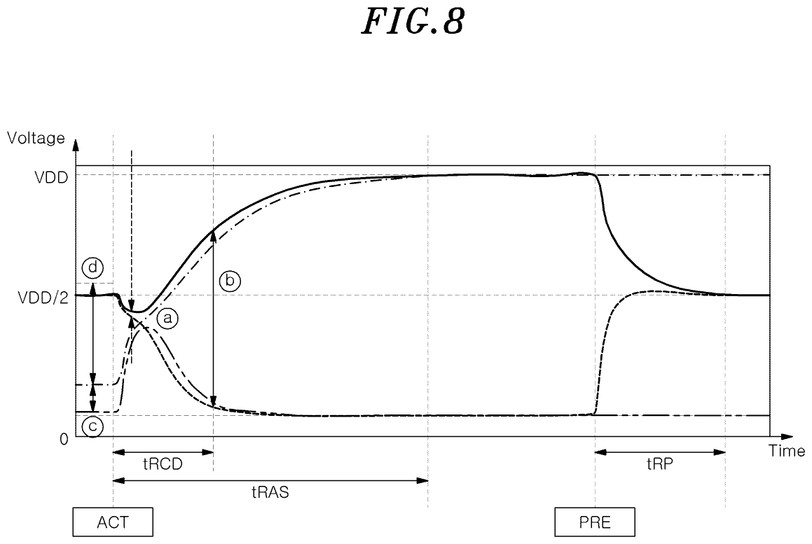

FIG. 5 is a diagram for describing the operation of the DRAM in the basic mode according to an embodiment of the present invention, FIG. 6 is a diagram illustrating a mat structure in a mode other than the basic mode of the DRAM according to an embodiment of the present invention, FIG. 7 is a diagram for describing the operation of the DRAM in the low-latency mode according to an embodiment of the present invention, and FIG. 8 is a diagram for describing the operation of the DRAM in the low-power mode according to an embodiment of the present invention.

The mat structure when the DRAM according to an embodiment of the present invention is in the basic mode is as illustrated in FIG. 4. When the basic mode is selected by the mode register and then the address command is received, the first mat may activate first interest arrays corresponding to the received address command to provide a data voltage higher than a reference voltage from a cell of at least one of the first interest arrays to the bitline sense amplifier. Here, the reference voltage may refer to the V_{DD}/2, which is half of the V_{DD}, and the data voltage may refer to a voltage indicating that data is stored. In addition, the second mat may deactivate second interest arrays corresponding to the first interest arrays to provide a reference voltage from a cell of at least one of the second interest arrays to the bitline sense amplifier.

As a result, in the basic mode, the DRAM according to an embodiment of the present invention may operate as illustrated in FIG. 5. Basically, in the basic mode, the DRAM may operate similarly to the open bitline structure of FIG. 3.

Specifically, in the activation step, a global decoder may select one array, and the bitline sense amplifier of the selected mat may read data from one of the paired rows. In this case, the other array of the paired rows may be deactivated to provide the V_{DD}/2 voltage to the bitline sense amplifier.

In the basic mode, there may be provided an environment in which information may be stored in all cells and the entire capacity of the DRAM may be utilized.

Meanwhile, the DRAM according to an embodiment of the present invention may operate in a mode other than the basic mode for faster access or lower power consumption.

As illustrated in FIG. 6, when the low-latency mode is selected by the mode register and then the address command is received, the first mat may activate the first interest array corresponding to the received address command to provide the data voltage higher than the reference voltage from the cell of at least one of the first interest arrays to the bitline sense amplifier. In addition, the second mat may activate the second interest array corresponding to the first interest array to provide an opposite voltage to the data voltage from the cell of at least one of the second interest arrays to the bitline sense amplifier.

To this end, when the low-latency mode is selected by the mode register, the first mat and the second mat may store the data voltage and the opposite voltage in each cell corresponding to each of the first bitline and the second bitline connected to the same bitline sense amplifier.

Referring to FIG. 7, in the low-latency mode, the DRAM according to an embodiment of the present invention may store information with opposite voltages in a bitline pair of one bitline sense amplifier in two cells. In this case, the cells are located in paired adjacent mats and may be activated simultaneously.

In the activation mode, the global decoder may select an array pair, and the opposite voltage of the complementary cell may flow in the bitline sense amplifier through two bitlines, and the bitline sense amplifier may generate a larger voltage difference so that the bitline sense amplifier may quickly and strongly detect the information.

On the other hand, when the low-power mode is selected by the mode register and then the address command is received, the first mat may activate the first interest array corresponding to the received address command to provide a data voltage lower than the reference voltage from the cell of at least one of the first interest arrays to the bitline sense amplifier. In addition, the second mat may activate the second interest arrays corresponding to the first interest arrays to provide an opposite voltage to the data voltage from the cell of at least one of the second interest arrays to the bitline sense amplifier.

To this end, when the low-latency mode is selected by the mode register, the first mat and the second mat may store the data voltage and the opposite voltage in each cell corresponding to each of the first bitline and the second bitline connected to the same bitline sense amplifier.

Referring to FIG. 8, in the low-power mode, the DRAM according to an embodiment of the present invention may increase a refresh interval of the DRAM by using a stronger sensing capability. That is, the low-power mode can have a second update cycle that is longer than a first update cycle of the basic mode and the low-latency mode.

In addition, in the DRAMs of FIGS. 2 and 3, the charged cells should be maintained at the reference voltage V_{DD}/2 or higher, and needs to hold sufficient charge of a reasonable threshold value or greater (e.g., up to 0.65V). On the other hand, the charged cells of the DRAM according to an embodiment of the present invention may be much lower than the V_{DD}/2 voltage level as long as an original bitline and a complementary bitline have the voltage difference that may be detected.

As a result, a minimum cell voltage level may be significantly reduced compared to the conventional one (e.g., up to 0.16 V).

Meanwhile, the mode register of the DRAM according to an embodiment of the present invention may select the basic mode when the memory usage is greater than or equal to the reference usage, and select one of the low-latency mode or the low-power mode when the memory usage is less than the reference usage. Here, the reference usage may refer to the minimum memory usage that is suitable for operation according to the basic mode.

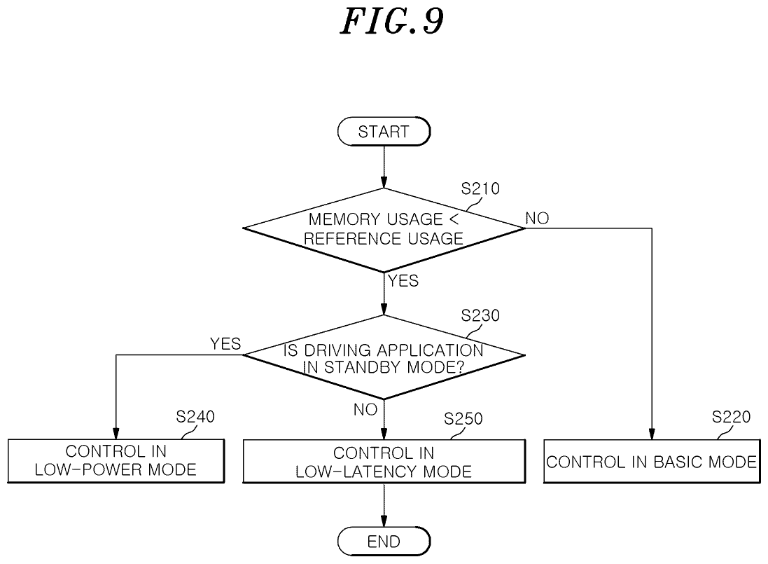

Hereinafter, a method for switching a mode of a DRAM according to an embodiment of the present invention will be described with reference to FIG. 9.

FIG. 9 is a flowchart of a method for controlling a DRAM according to an embodiment of the present invention.

First, the mode register of the DRAM according to an embodiment of the present invention may identify whether the memory usage is less than the reference usage (S210). When the memory usage is greater than or equal to the reference usage, the mode register of the DRAM according to an embodiment of the present invention may select the basic mode to control the DRAM (S220).

On the other hand, when the memory usage is less than the reference usage, the mode register of the DRAM according to an embodiment of the present invention may identify whether a driving application is in a standby mode among the application driving methods (S230). When the driving application is in the standby mode, the mode register of the DRAM according to an embodiment of the present invention may select the low-power mode to control the DRAM (S240).

On the other hand, when the driving application is not in the standby mode, the mode register of the DRAM according to an embodiment of the present invention may select the low-latency mode to control the DRAM (S250).

FIG. 9 illustrates an embodiment of a mode switching method between the low-power mode and the low-latency mode according to the driving method of the driving application. In addition, the DRAM according to an embodiment of the present invention may variously set mode switching conditions within the technical concept of using the low-power mode under specific conditions where the power consumption may be reduced and using the low-power mode under specific conditions where the performance needs to increase.

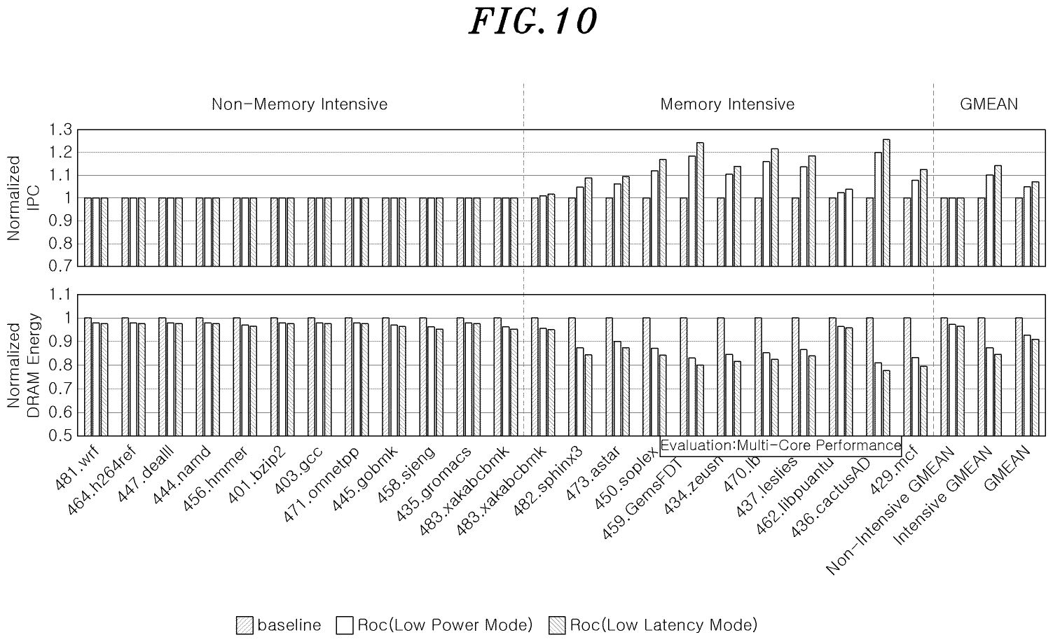

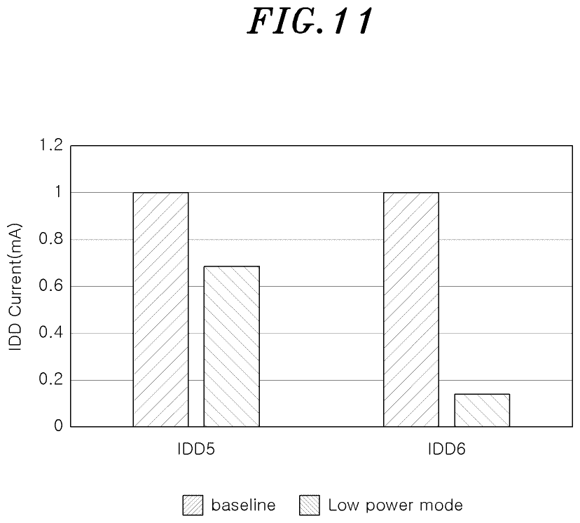

The method for controlling a DRAM according to an embodiment of the present invention has been described so far. Hereinafter, the performance of the DRAM according to an embodiment of the present invention will be described with reference to FIGS. 10 and 11.

FIG. 10 is a graph comparing the energy consumption of the DRAM according to an embodiment of the present invention, and FIG. 11 is a graph comparing refresh current consumption in a low-power mode of a mirror-structured mat according to an embodiment of the present invention.

The graph of FIG. 10 is a graph comparing IPC/Energy between baseline open bitline architecture and various modes of the DRAM according to an embodiment of the present invention. Overall, it may be confirmed that the low-latency mode may accelerate single-core execution by 6.9% on average using 23 SPEC CPU 2006 benchmarks. In addition, the low-latency mode may reduce DRAM energy consumption by 9.0% on average.

Furthermore, as illustrated in FIG. 11, it may be confirmed that the low-power mode may reduce DRAM standby and refresh current by 31.6% and 85.7% on average, respectively.

In this way, according to an embodiment of the present invention, by using the structure including the bitline sense amplifiers shared by the bitlines of each adjacent mat, it is possible to dynamically switch the capacity that is not fully utilized in order to improve the latency and power consumption while minimizing the area overhead. As a result, by improving the DRAM access latency by utilizing the unused capacity, it is possible to increase the application speed. In addition, by dynamically switching the capacity and reducing the times of number of the refresh operation, it is possible to extend the usage time of the battery-driven device.

Combinations of each block of the block diagrams and each step of the flowchart attached to the present disclosure may be performed by computer program instructions. Since these computer program instructions can be installed in an encoding processor of a general-purpose computer, a special-purpose computer, or other programmable data processing equipment, the instructions executed through the encoding processor of the computer or other programmable data processing equipment generate means for executing functions described in each block of the block diagrams or each step of the flowchart. These computer program instructions may also be stored in a computer-usable or computer-readable memory that can be directed to computers or other programmable data processing equipment to implement functions in a particular way, and thus the instructions stored in the computer-usable or computer-readable memory can also produce manufactured items containing instruction means for executing the functions described in each block of the block diagram or each step of the flowchart. Since the computer program instructions can also be installed in a computer or other programmable data processing equipment, a series of operational steps may be performed on the computer or other programmable data processing equipment to create a process that is executed by the computer, thereby providing steps for executing the functions described in each block of the block diagrams and each step of the flowchart through the instructions.

Additionally, each block or each step may represent a module, a segment, or some code that includes one or more executable instructions for executing specified logical function(s). Additionally, it should be noted that, in some alternative embodiments, the functions mentioned in blocks or steps are executed out of order. For example, two blocks or steps shown in succession may be performed substantially simultaneously, or the blocks or steps may sometimes be performed in reverse order depending on the corresponding function.

What is claimed is:

1. A DRAM (Dynamic Random Access Memory) including a plurality of mats composed of cell arrays, comprising:
a first mat including a first cell array that is aligned by first bitlines and first wordlines;
a second mat including a second cell array that is adjacent to the first mat and aligned by second bitlines and second wordlines; and
a bitline sense amplifier shared by the first bitlines of the first mat and the second bitlines of the second mat,
wherein the bitline sense amplifier connected to the first mat is shared only with the second mat.

2. The DRAM of claim 1, wherein the bitline sense amplifier includes a first input terminal that is connected to one of the first bitlines and a second input terminal that is connected to one of the second bitlines corresponding to the first bitline connected to the first input terminal.

3. The DRAM of claim 1, further comprising a mode register that selects one of a basic mode, a low-latency mode, or a low-power mode based on memory usage of a server to which the DRAM belongs and an application operating method.

4. The DRAM of claim 3, wherein, when the basic mode is selected by the mode register and then an address command is received,
the first mat activates one of first interest arrays corresponding to the received address command to provide a data voltage higher than a reference voltage from a cell of at least one of a cell of the first interest arrays to the bitline sense amplifier, and
the second mat may deactivate second interest arrays corresponding to the first interest arrays to provide the reference voltage from a cell of at least one of the second interest arrays to the bitline sense amplifier.

5. The DRAM of claim 3, wherein, when the low-latency mode is selected by the mode register and then an address command is received,
the first mat activates first interest arrays corresponding to the received address command to provide a data voltage higher than a reference voltage from a cell of at least one of the first interest arrays to the bitline sense amplifier, and
the second mat activates second interest arrays corresponding to the first interest arrays to provide an opposite voltage to the data voltage from a cell of at least one of the second interest arrays to the bitline sense amplifier.

6. The DRAM of claim 5, wherein, when the low-latency mode is selected by the mode register, the first mat and the second mat store the data voltage and the opposite voltage in each cell corresponding to each of a first bitline and a second bitline connected to the same bitline sense amplifier.

7. The DRAM of claim 3, wherein, when the low-power mode is selected by the mode register and then an address command is received,
the first mat activates first interest arrays corresponding to the received address command to provide a data voltage lower than a reference voltage from a cell of at least one of the first interest arrays to the bitline sense amplifier, and
the second mat activates second interest arrays corresponding to the first interest arrays to provide an opposite voltage to the data voltage from a cell of at least one of the second interest arrays to the bitline sense amplifier.

8. The DRAM of claim 3, wherein the low-power mode has a second update cycle longer than a first update cycle of the basic mode and the low-latency mode,
the mode register selects the basic mode when the memory usage is greater than or equal to reference usage, and
selects one of the low-latency mode or the low-power mode when the memory usage is less than the reference usage.

9. The DRAM of claim 8, wherein, when the low-latency mode is selected and then the application driving method is in a standby mode, the mode register selects the low-power mode.

10. The DRAM of claim 1, wherein the second cell array stores opposite data or independent data of the first cell array.

11. A method for controlling a DRAM including a bitline sense amplifier shared by first bitlines of a first mat and second bitlines of a second mat adjacent to the first mat, the method comprising:
identifying memory usage and an application operation method of a server to which the DRAM belongs;
selecting one of a basic mode, a low-latency mode, or a low-power mode based on the memory usage and the application operating method; and
controlling the first mat and the second mat according to the selected mode,
wherein the bitline sense amplifier connected to the first mat is shared only with the second mat.

12. The method of claim 11, wherein the bitline sense amplifier includes a first input terminal that is connected to one of the first bitlines and a second input terminal that is connected to one of the second bitlines corresponding to the first bitline connected to the first input terminal.

13. The method of claim 11, wherein the controlling the first mat and the second mat according to the selected mode includes:
receiving an address command after the basic mode is selected;
activating first interest arrays of the first mat corresponding to the received address command to provide a data voltage higher than a reference voltage from a cell of at least one of the first interest arrays to the bitline sense amplifier; and
deactivating second interest arrays of the second mat corresponding to the first interest arrays to provide the reference voltage from a cell of at least one of the second interest arrays to the bitline sense amplifier.

14. The method of claim 11, wherein the controlling the first mat and the second mat according to the selected mode includes:
receiving an address command after the low-latency mode is selected;
activating first interest arrays of the first mat corresponding to the received address command to provide a data voltage higher than a reference voltage from a cell of at least one of the first interest arrays to the bitline sense amplifier; and
activating second interest arrays of the second mat corresponding to the first interest arrays to provide an opposite voltage to the data voltage from a cell of at least one of the second interest arrays to the bitline sense amplifier.

15. The method of claim 14, wherein the controlling the first mat and the second mat according to the selected mode further includes storing the data voltage and the opposite voltage in each cell of the first mat and the second mat corresponding to each of the first bitline and the second bitline connected to the same bitline sense amplifier, when the low delay mode is selected.

16. The method of claim 11, wherein the controlling the first mat and the second mat according to the selected mode includes:
receiving an address command after the low-power mode is selected;
activating first interest arrays of the first mat corresponding to the received address command to provide a data voltage lower than a reference voltage from a cell of at least one of the first interest arrays to the bitline sense amplifier; and
activating second interest arrays of the second mat corresponding to the first interest arrays to provide an opposite voltage to the data voltage from a cell of at least one of the second interest arrays to the bitline sense amplifier.

17. The method of claim 11, wherein the low-power mode has a second update cycle longer than a first update cycle of the basic mode and the low-latency mode, and
the selecting one of the basic mode, the low-latency mode, or the low-power mode includes:
selecting the basic mode when the memory usage is greater than or equal to reference usage; and
selecting one of the low-latency mode or the low-power mode when the memory usage is less than the reference usage.

18. The method of claim 17, wherein the selecting one of the low-latency mode or the low-power mode further includes selecting the low-power mode when the selection changes from the basic mode to the low-latency mode and then the application driving method is in a standby mode.

19. The method of claim 11, wherein, in the controlling the first mat and the second mat according to the selected mode, it is controlled whether to store independent data or opposite data in the first mat and the second mat according to the selected mode.

20. A method for controlling a DRAM including a bitline sense amplifier shared by first bitlines of a first mat and second bitlines of a second mat adjacent to the first mat, the method comprising:
identifying memory usage and an application operation method of a server to which the DRAM belongs;
selecting one of a basic mode, a low-latency mode, or a low-power mode based on the memory usage and the application operating method; and
controlling the first mat and the second mat according to the selected mode,
wherein the low-power mode has a second update cycle longer than a first update cycle of the basic mode and the low-latency mode, and
the bitline sense amplifier connected to the first mat is shared only with the second mat.
